(19) United States
(12) Patent Application Publication
(10) Pub. No.: US 2018/0153231 A1
(43) Pub. Date: Jun. 7, 2018

(54) FUNCTIONAL CLOTHING

(71) Applicant: KOLON INDUSTRIES, INC., Gwacheon-si, Gyeonggi-do (KR)

(72) Inventors: Ja Ram KU, Yongin-si (KR); Hong Kwan PARK, Yongin-si (KR); Yoon Young CHOI, Yongin-si (KR); Soo Jin WOO, Yongin-si (KR); Hee Jung SHIN, Yongin-si (KR); Sae Yong AN, Yongin-si (KR); Si Nae KANG, Yongin-si (KR)

(73) Assignee: KOLON INDUSTRIES, INC., Gwacheon-si, Gyeonggi-do (KR)

(21) Appl. No.: 15/576,066

(22) PCT Filed: May 18, 2016
(86) PCT No.: PCT/KR2016/005247

§ 371 Date: Nov. 21, 2017

(30) Foreign Application Priority Data
May 26, 2015 (KR) 10-2015-0073237

(51) Int. Cl. A41D 13/01; A41D 1/00

(52) U.S. Cl. CPC A41D 13/01; H05K 9/009; A41D 1/002

(57) ABSTRACT

Functional clothing containing an outer skin and an inner skin is provided. The outer skin is formed to be normal outdoor clothing and has a light emitting part attached thereto. The inner skin has an organic solar cell, an electric wire and a battery, and produces and stores electricity by the organic solar cell. The electricity is utilized for various uses such as allowing the light emitting part to emit light or charging a mobile phone outdoors. The electric wire is formed with a silver nanowire in order to increase wear sensation and prevent electric wire short circuiting and is formed in a zigzag pattern in a state in which the fabric is stretched. The clothing is also provided with a temperature sensor, which is useful to locate its wearer by allowing the light emitting part to emit light during an accident.

### TECHNICAL FIELD

The present invention relates to functional clothing, and more particularly, to functional clothing, which includes an outer garment, at which a light-emitting unit is detachably provided, and an inner garment, which is detachably coupled to the outer garment, to which an organic solar cell is mounted, and at which a wire is formed.

### BACKGROUND ART

With the recent social trend of regarding leisure activities as important, people who enjoy various outdoor activities such as camping, hiking, and marine leisure are increasing. Accordingly, various outdoor equipment is also being developed. Various functions are being added to original functions of camping equipment or climbing clothes.

For example, Patent Registration No. 10-1035442 relates to clothing, to which an LED substrate is mounted so as to realize light emission using the flexible LED substrate while worn. However, an LED substrate or a power supply device is vulnerable to moisture, and although waterproof coating is applied to the same, the performance thereof is deteriorated due to frequent washing and exposure to moisture. Further, a separate battery is required for supply of power, which causes inconvenience in that the battery needs to periodically charged or replaced.

Therefore, there is a need for developing functional clothing, which is capable of self-generating and storing electricity without the necessity of replacement of a separate battery. Further, there is a need for developing functional clothing, which is capable of preventing damage to a wire provided therein and preventing deterioration of a wearing sensation despite frequent folding or friction due to the characteristics of outdoor clothing. Furthermore, there is a need for developing functional clothing that may be easily washed.

### DISCLOSURE

### Technical Problem

An object of the present invention is to provide functional clothing, which may be applied to outdoor clothing and which is capable of self-generating, storing and supplying electricity.

Another object of the present invention is to provide functional clothing, which may be easily washed and may provide a good wearing sensation.

A further object of the present invention is to provide functional clothing, which is capable of autonomously determining a distress situation and indicating the distress situation by emitting light.

### Technical Solution

In order to achieve the above objects of the present invention, functional clothing according to an embodiment of the present invention includes an outer garment and an inner garment. The outer garment is provided with a light-emitting unit, which is detachable from the outer garment. The inner garment is detachably coupled to the outer garment, is provided with an organic solar cell, and has a wire formed at a surface thereof.

In the functional clothing according to another embodiment of the present invention, the wire may be formed of one selected from among silver, copper, nickel, carbon black, graphite, and metal oxide.

In the functional clothing according to another embodiment of the present invention, the wire may be embodied as a fabric strap coated with one selected from among silver, copper, nickel, carbon black, graphite, and metal oxide.

In the functional clothing according to another embodiment of the present invention, the outer garment and the inner garment may be electrically connected to each other by connectors.

In the functional clothing according to another embodiment of the present invention, the inner garment may be further provided with a gyro sensor. The gyro sensor may sense inclination of a user's body and may activate the light-emitting unit to emit light in accordance with the sensing result.

In the functional clothing according to another embodiment of the present invention, the inner garment may be further provided with a temperature sensor. When a user's body temperature falls below a predetermined value, the temperature sensor may activate the light-emitting unit to emit light.

The functional clothing according to another embodiment of the present invention may include an outer garment, an intermediate garment and an inner garment. The outer garment may be provided with a light-emitting unit, which is detachable from the outer garment. The intermediate garment may be detachably coupled to the outer garment, may be provided with an organic solar cell, and may have a wire formed at a surface thereof. The inner garment may be detachably coupled to the intermediate garment.

In the functional clothing according to another embodiment of the present invention, the intermediate garment may be formed of a mesh material.

### Advantageous Effects

The functional clothing of the present invention is capable of self-producing electricity, using the electricity for various convenience devices, and storing the produced electricity.

The functional clothing of the present invention provides a good wearing sensation and can be easily washed even though it is provided with an organic solar cell and a wire.

The functional clothing of the present invention is capable of autonomously determining a distress situation using a sensor and indicating the distress situation.

### DESCRIPTION OF DRAWINGS

FIG. 1 is a view illustrating functional clothing according to an embodiment of the present invention.

FIG. 2 is a view illustrating the front appearances of an outer garment and an inner garment of the functional clothing according to the embodiment of the present invention.

FIG. 3 is a view illustrating the rear appearances of the outer garment and the inner garment of the functional clothing according to the embodiment of the present invention.

FIG. 4 is a view illustrating a wire in the functional clothing according to the embodiment of the present invention.

FIG. 5 is a view illustrating the wire in the functional clothing according to the embodiment of the present invention.

FIG. 6 is a view illustrating a process of forming a wire in the state in which cloth is stretched in the functional clothing according to the embodiment of the present invention.

FIG. 7 is a view illustrating electromagnetic-wave-shielding cloth in the functional clothing according to the embodiment of the present invention.

FIG. 8 is a view illustrating the electromagnetic-wave-shielding cloth in the functional clothing according to the embodiment of the present invention.

FIG. 9 is a view illustrating the coupling of the outer garment and the inner garment in the functional clothing according to the embodiment of the present invention.

FIG. 10 is a view illustrating connectors for coupling the outer garment and the inner garment to each other in the functional clothing according to the embodiment of the present invention.

FIG. 11 is a sectional view of the state in which the outer garment and the inner garment are coupled to each other in the functional clothing according to the embodiment of the present invention.

FIG. 12 is a view illustrating light emission from a light-emitting unit in the functional clothing according to the embodiment of the present invention.

FIG. 13 is a view illustrating functional clothing according to another embodiment of the present invention.

### BEST MODE

Hereinafter, preferred embodiments of the present invention will be described in detail with reference to the accompanying drawings. Here, it is noted that the same element in the accompanying drawings is denoted with the same reference numeral as far as possible. Further, a detailed description of known functions and configurations incorporated herein will be omitted when the same may obscure the subject matter of the present invention. For the same reason, some of the elements are exaggerated, omitted or simplified in the accompanying drawings.

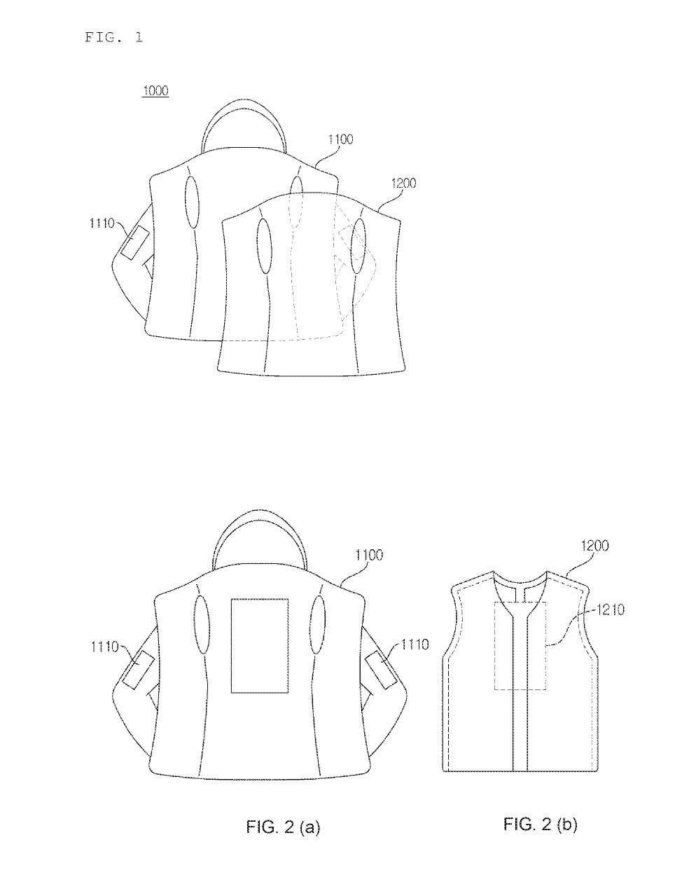

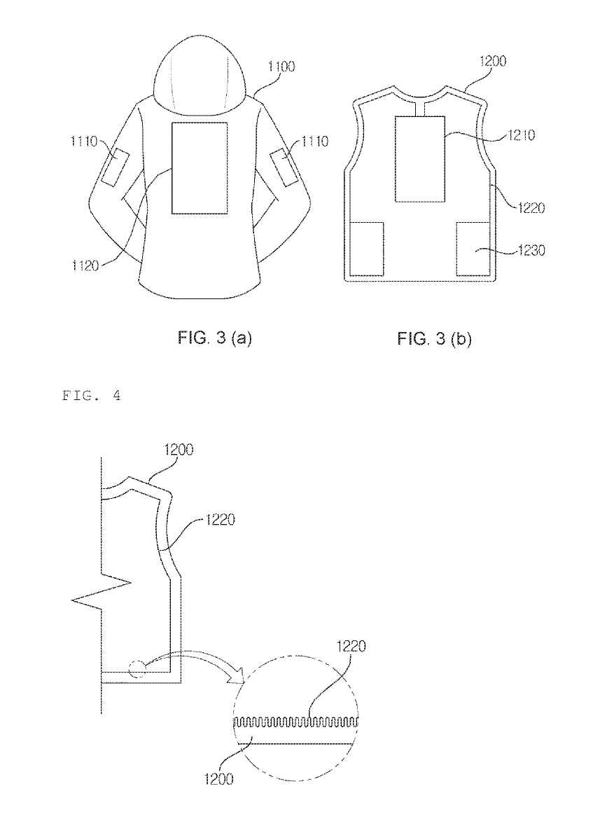

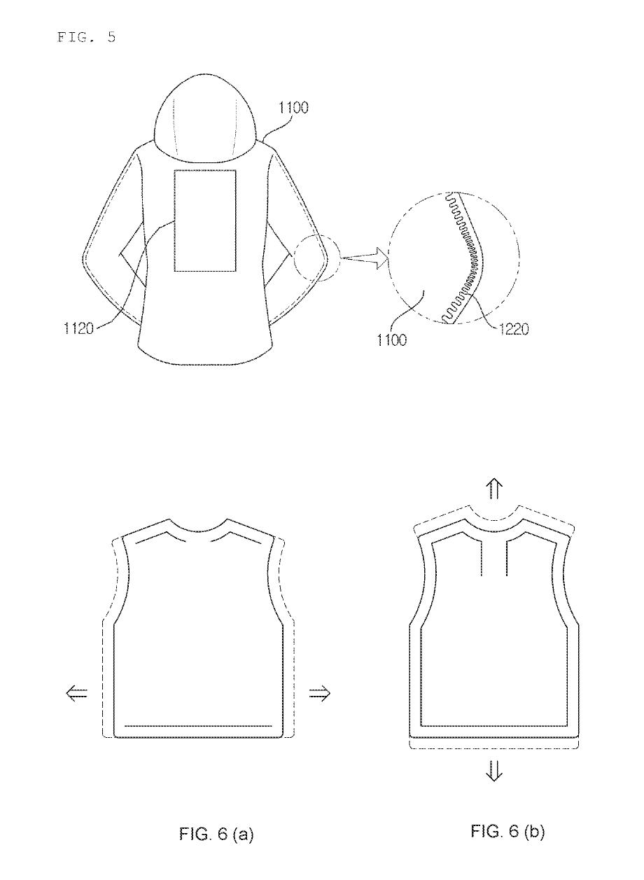

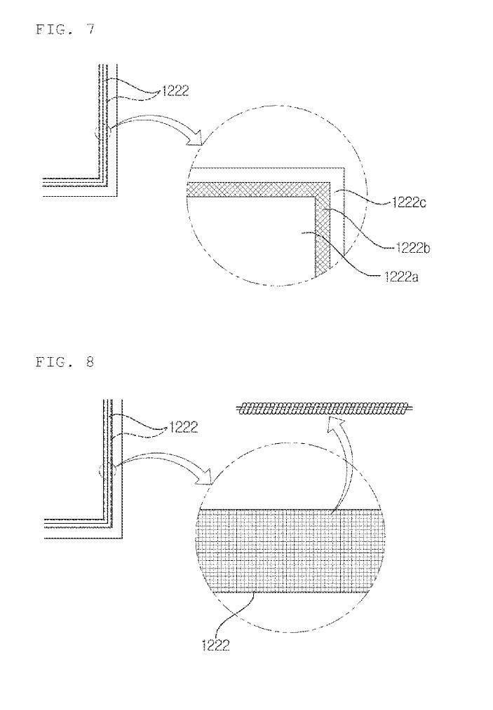

FIG. 1 is a view illustrating functional clothing according to an embodiment of the present invention, FIG. 2 is a view illustrating the front appearances of an outer garment and an inner garment of the functional clothing according to the embodiment of the present invention, FIG. 3 is a view illustrating the rear appearances of the outer garment and the inner garment of the functional clothing according to the embodiment of the present invention, FIGS. 4 and 5 are views illustrating a wire in the functional clothing according to the embodiment of the present invention, and FIG. 6 is a view illustrating a process of forming a wire in the state in which cloth is stretched in the functional clothing according to the embodiment of the present invention.

As shown in FIG. 1, the functional clothing 1000 according to the embodiment of the present invention includes an outer garment 1100 and an inner garment 1200. The outer garment 1100 may be formed of a polyester material or a Gore-Tex material. The outer garment 1100 may be configured in the design of a general outdoor jacket, and the design thereof may vary in consideration of functionality. The outer garment 1100 is provided with a light-emitting unit 1110. The light-emitting unit 1110 may be formed in various patterns in accordance with the purpose of the functional clothing. The light-emitting unit 1110 may be embodied as a compact LED bulb array or an LED band. The light-emitting unit 1110 may be attached to or detached from the outer garment using a piece of Velcro tape or a snap. The light-emitting unit 1110 is provided with a connector for power connection. The light-emitting unit 1110 may be attached to arm portions or a back portion of the outer garment 1100.

The inner garment 1200 may be detachably coupled to the inside of the outer garment 1100, and may be formed of a polyester material. However, there are no material restrictions, and an elastic material may be used or a mesh material may be used.

The inner garment 1200 is equipped with an organic solar cell 1210 (an organic thin-film solar cell). The organic solar cell 1210 is a device that converts light energy into electric energy using a photovoltaic effect, and has been in the spotlight due to its light weight and flexibility. According to the present invention, various functionalities are given to clothing using the organic solar cell, which enables the production and use of electricity even outdoors.

The organic solar cell 1210 includes a plurality of cells, each of which absorbs light and generates electric energy, and which constitutes a single unit by being arranged in a stripe pattern, and the single unit, which is formed through a combination of a plurality of cells, is referred to as a module. A plurality of modules of the organic solar cell 1210 is arranged suitably for the shape and the size of the inner garment in order to absorb the sunlight. The organic solar cell 1210 may be placed at a portion of the garment that is the most exposed to the sun while worn.

When the organic solar cell 1210 is placed, the organic solar cell 1210 may be attached using a foam-adhesive composition. The thin film of the organic solar cell 1210, which generates electric current, has a very small thickness of several hundreds of nm, and the thickness of the organic solar cell module is not more than several hundreds of μm, even including the thicknesses of a base film and a laminate, and thus the organic solar cell is vulnerable to external shocks such as scratches. Therefore, a shock-absorbing region may be formed when the organic solar cell is attached to the cloth, in order to prevent damage attributable to shocks due to outdoor activities. When the organic solar cell 1210 is attached to the cloth, a foam-adhesive composition may be applied to an adhesive base layer. In the foam-adhesive composition, bubbles are formed when an adhesive composition is mixed with a foam component and is hardened. The bubbles formed on the adhesive layer functions to absorb external shocks when the same are applied to the organic solar cell.

In the foam-adhesive composition, the foam is ethylene, particularly low-density or very-low-density polyethylene (PE) (LDPE, LLDPE, VLDPE) homopolymer or copolymer, ethylene-vinyl acetate copolymer (EVA), or a mixture of the aforementioned polymers (for example, PE-EVA foam). An additional polymer may include polyvinyl acetate, polypropylene, ethylene-propylene-diene rubber (EPDM), thermoplastic elastomer based on styrene block copolymer, polyurethane based on aromatic and aliphatic diisocyanate, polyvinyl chloride (PVC), polychloroprene, natural rubber, and acrylate copolymer. The foam may be embodied as cross-linked or non-cross-liked foam. Preferably, polyethylene, ethylene-vinyl acetate (EVA), polypropylene (PP), or polyurethane (PU) foam may be used as a foam carrier. Since the organic solar cell produces electricity by absorbing light, it is desirable for the foam to be transparent. Although, in this embodiment, a foam-adhesive composition is used to attach the organic solar cell 1210 to the inner garment 1200, the embodiment is not limited thereto, and a general adhesive composition such as epoxy may alternatively be used. In the case in which a general adhesive composition is used, the adhesive composition may be coated on the inner garment 1200 and the organic solar cell 1210 may be attached thereto, or the adhesive composition may be coated on the two opposite surfaces of the laminating film and the surfaces may respectively be attached to the inner garment 1200 and the organic solar cell 1210 so as to fix the positions thereof.

Meanwhile, a waterproof film or a sealing material may further be applied to the upper portion of the organic solar cell 1210 so as to minimize the effect of shocks or moisture. It is also desirable for the sealing material to be formed of a transparent material so as not to interrupt sunlight absorption by the organic solar cell.

As shown in FIG. 3, when the outer garment 1100 and the inner garment 1200 are coupled to each other, the region 1120 of the outer garment 1100 that corresponds to the region of the inner garment 1200 at which the organic solar cell 1210 is disposed may be formed of a transparent material. As a result of the region of the outer garment 1200 that corresponds to the position of the organic solar cell 1210 being formed of a transparent material, the operation of absorbing sunlight of the organic solar cell 1210 is not affected. Although, in this embodiment, a portion of the outer garment 1100 is formed of a transparent material, another embodiment may be configured such that an opening is formed in the region 1120 of the outer garment 1100 that corresponds to the position of the organic solar cell 1210 so as to allow the organic solar cell 1210 to be directly exposed outside.

Meanwhile, the inner garment 1200 is provided with a wire 1220, through which electricity produced by the organic solar cell 1210 flows. In order to store and use electricity produced by the organic solar cell 1210 mounted to outdoor equipment, a wire and a battery need to be provided in the outdoor equipment. However, if a wire is attached to fabric, there is a problem in that the wire deteriorates the wearing sensation or is easily cut due to the characteristics of the fabric. In order to prevent this, in the present invention, the wire 1220 is formed directly on the inner garment 1200, thereby improving the wearing sensation. The wire 1220 may be embodied as a silver nanowire, and may be formed on the inner garment 1200 using silver nanoprinting or an electron beam. Because silver (Ag) has high ductility and flexibility, it is easy to form a thin film or a fine wire using the same. Further, silver has the highest electric conductivity among metals. Therefore, in the case in which the wire 1220 is formed of silver, it is possible to form a wire having a small thickness while having high electric conductivity, thereby improving the wearing sensation of the functional clothing. In another embodiment, in the process of forming the wire, a conductive paste, which includes powders of metal such as copper or nickel, carbon black, graphite, and metal oxide such as tin oxide or indium oxide, may be used.

As shown in FIG. 4, the wire 1220 may be formed in a fine zigzag shape, rather than a straight line shape. Because the user continuously moves while wearing clothing, there is a concern of the wire being cut due to the movement. In particular, because a user wearing outdoor clothing tends to be very active, the wire formed on the clothing is exposed to more shocks and movement. Therefore, the wire is formed in a zigzag shape so as to endure shocks attributable to movement or wrinkling of the cloth.

As shown in FIG. 5, in the functional clothing according to the present invention, the wire has a zigzag pattern such that a portion of the wire positioned corresponding to a portion of the clothing that is subject to relatively small shocks is sparsely formed and such that a portion of the wire positioned corresponding to a joint portion such as an elbow or a knee or a portion of the clothing that is frequently folded or is subject to relatively large shocks is densely formed.

Further, in order to cope with the situation in which the clothing stretches, the wire may be patterned in the state in which the cloth is stretched. In the case in which the clothing is formed of cloth having great elasticity, there may occur a problem in that the wire is cut as the clothing stretches. In order to prevent this, the wire is patterned after the cloth is stretched in the direction in which the wire is formed. As shown in FIG. 6, when the wire is to be formed in the horizontal direction, the wire is patterned after the cloth is stretched left and right. When the cloth is restored to its original state after the formation of the wire, the pattern of the wire becomes dense, and accordingly, even when the cloth stretches, the wire is not cut, and thus enables the flow of current therethrough. When the wire is to be formed in the vertical direction, the wire may be patterned after the cloth is stretched up and down (FIG. 6b). When the cloth is stretched, it is desirable to evenly pull the entire edge of the cloth so that constant tension is applied to the cloth. If cloth having great elasticity is used, the cloth needs to be stretched to a length that is at most 1.3 times as long as the original length of the cloth in order to prevent the cloth from being excessively stretched.

In another embodiment, the wire may be formed in the manner of sewing a strap-shaped wire on the inner garment 1200. The strap-shaped wire is formed by coating a fabric strap having a constant width with silver. Silver may be coated on the entirety of the areas of the front and rear surfaces of the fabric strap, or may be coated only on the front surface or a portion thereof. In the case in which silver is coated only on a portion of the fabric strap, it may be formed in a straight-line shape or a zigzag shape. If silver is coated in a zigzag shape, even when the cloth stretches due to outdoor activity, it is possible to further prevent the wire from being damaged, for example, from being cut.

The fabric strap may be formed of the same cloth as the inner garment, or may be formed of an elastic cloth. When an elastic cloth is used, the fabric strap may first be stretched in the longitudinal direction thereof, and silver may then be coated thereon. That is, after the fabric strap is stretched, silver may be coated on the entire area of the fabric or may be formed in a straight-line pattern or a zigzag pattern. Silver may be coated to a thickness ranging from 15 to 20 μm. The fabric coated with silver is placed at a position where a wire needs to be formed and is then sewn and fixed to the inner garment 1200.

Meanwhile, although, in this embodiment, the fabric is coated with silver, a conductive paste, which includes powders of metal such as copper or nickel, carbon black, graphite, and metal oxide such as tin oxide or indium oxide, may be used instead of silver.

In a further embodiment, a sewing thread may be used as a wire by applying a silver nanocoating thereon. A wire is formed by sewing the silver-nano coated sewing thread at a position where a wire needs to be formed. When the sewing is performed, the silver-nano coated sewing thread may be applied to both an upper thread and a lower thread, or may be applied to either the upper thread or the lower thread. In the case in which the silver-nano coated sewing thread is used, it is possible to form a wire merely by sewing the same.

The inner garment 1200 is provided with a battery 1230 for storing the produced electricity. Among the various kinds of batteries, any one may be used as the battery 1230 so long as it can store electric energy and can be used as a power source. In this embodiment, a lithium battery having a light weight and good charging efficiency is used.

The present invention may have various functions, for example, may produce and store electricity and may use the stored electricity. Although this embodiment is equipped with the light-emitting unit 1110 in order to use the same as illumination, the embodiment may have a function of charging a cell phone in a wired or wireless manner.

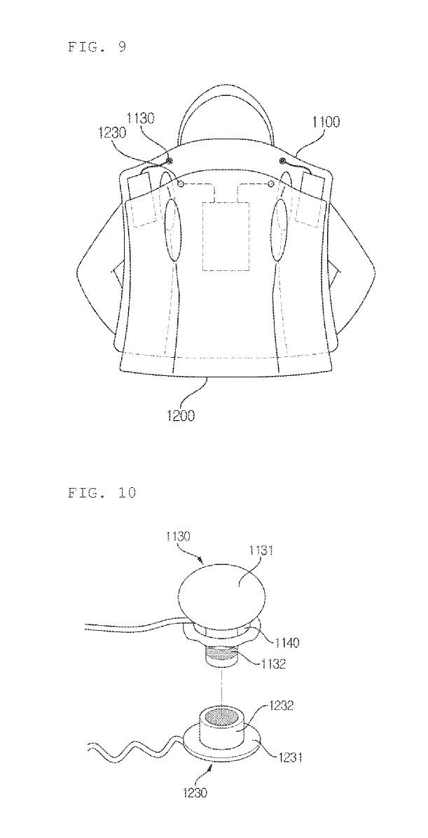

FIGS. 7 and 8 are views illustrating electromagnetic-wave-shielding cloth in the functional clothing according to the embodiment of the present invention.

Meanwhile, when the produced electricity is stored and used, electromagnetic waves are generated in the functional clothing. Because the functional clothing is maintained very close to the human body, the electromagnetic waves have an effect on the user's body. In order to minimize the effect of the electromagnetic waves, in the embodiment of the present invention, electromagnetic-wave-shielding cloth is placed over the organic solar cell and the wire.

As shown in FIG. 7, the electromagnetic-wave-shielding cloth 1222 is placed over the upper portion and the lower portion of the inner garment, on which the wire 1220 is disposed, and is sewn thereto. The electromagnetic-wave-shielding cloth 1222 may be formed by interposing a metal mesh 1222b between two layers of cloth 1222a and 1222c. Each of the holes formed in the metal mesh 1222b is formed to be smaller than the wavelength of the electromagnetic waves. Here, the two layers of cloth 1222a and 1222c, which are sewn together, may employ waterproof cloth. The electromagnetic-wave-shielding cloth including the waterproof cloth may be brought into close contact with the inner garment by stitching the electromagnetic-wave-shielding cloth thereto and applying pressurized heat treatment to the same. Accordingly, it is possible to further prevent the wire 1220 from being damaged or being exposed to moisture. It is possible to block electromagnetic waves by placing the shielding cloth 1222 over the front and rear surfaces of the region at which the wire is formed. Besides the region at which the wire 1220 is disposed, the electromagnetic-wave-shielding cloth 1222 may also be placed over the regions below the regions at which the organic solar cell 1210, the battery 1230 and the electronic device are disposed.

In a further embodiment, as shown in FIG. 8, the electromagnetic-wave-shielding cloth 1222 may be manufactured using metal fiber, instead of interposing the metal mesh 1222b between the two layers of cloth 1222a and 1222c. The metal fiber may be manufactured in a manner such that conductive fiber, which is formed of metal such as silver or copper, is used as a core yarn and the core yarn is covered with natural or synthetic fiber. The diameter of silver or copper that serves as the core yarn may be 100 μm or less. In this embodiment, the metal fiber is manufactured by covering a 100 μm silver thread with a nylon thread, and the electromagnetic-wave-shielding cloth is manufactured by weaving the same. The woven metal fiber serves as a metal mesh, and a piece of woven cloth may function to block electromagnetic waves. The higher the density of the woven cloth, the finer the mesh. In a further embodiment, the electromagnetic-wave-shielding cloth may be manufactured by printing a mesh pattern on cloth using metal ink. In this case, the metal mesh portion may be disposed at an outward region in order to avoid direct contact with the wire.

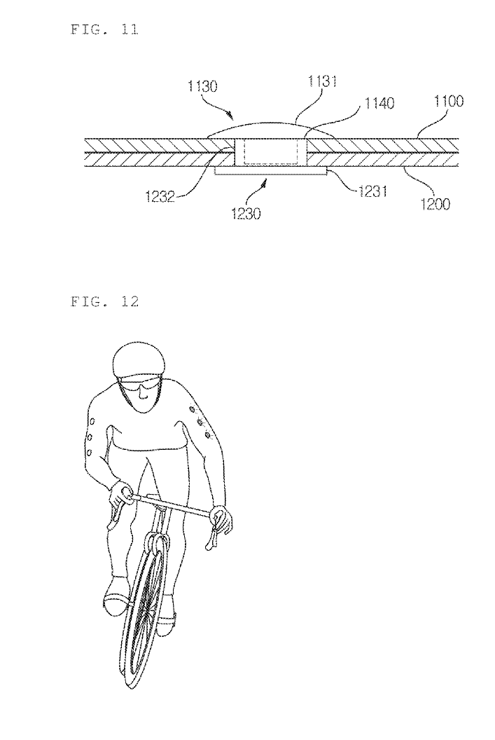

FIG. 9 is a view illustrating the coupling of the outer garment and the inner garment in the functional clothing according to the embodiment of the present invention, FIG. 10 is a view illustrating connectors for coupling the outer garment and the inner garment to each other in the functional clothing according to the embodiment of the present invention, and FIG. 11 is a sectional view of the state in which the outer garment and the inner garment are coupled to each other in the functional clothing according to the embodiment of the present invention.

As shown in FIG. 9, the outer garment 1100 and the inner garment 1200 are coupled to each other by connectors 1130 and 1230. The light-emitting unit 1110 is attached to the outer surface of the outer garment 1100, and is provided with a first connector 1130 for power connection. The outer garment 1100 has an opening 1140 formed therein, through which the first connector 1130 passes. A portion of the first connector 1130 passes through the opening 1140 and is coupled to a second connector 1230 provided at the inner garment. The first and second connectors 1130 and 1230 are embodied as snap buttons, which include a female button and a male button.

The first and second connectors 1130 and 1230 are formed of plastic and are partially plated with metal so that current may flow. As shown in FIG. 10, the first connector 1130 includes a first cover portion 1131 and a first body portion 1132. The bottom surface of the first cover unit 1130 and the outer circumferential surface of the first body portion 1132 are plated with metal. Meanwhile, the second connector 1230 includes a second cover portion 1231 and a second body portion 1232. The bottom surface of the second cover portion 1231 and the inner circumferential surface of the second body portion 1232 are plated with metal. Silver or copper may be used for plating. As shown in FIG. 11, through the coupling of the first and second connectors 1130 and 1230, the outer garment 1100 and the inner garment 1200 are coupled to each other and the outer circumferential surface of the first body portion 1132 and the inner circumferential surface of the second body portion 1232 may come into contact with each other. The first connector 1130 is connected to the light-emitting unit 1110, the second connector 1230 is connected to the wire formed at the inner garment 1200, and the outer garment 1100 and the inner garment 1200 are electrically connected to each other through the coupling of the first and second connectors 1130 and 1230. The first and second connectors 1130 and 1230 may be formed of plastic, or may be formed of silicon so as to easily come into close contact with each other when coupled.

Although, in this embodiment, the outer circumferential surface of the first connector 1130 and the inner circumferential surface of the second connector 1230 are wholly plated, the embodiment is not limited thereto, and in another embodiment, the outer circumferential surface of the first connector 1130 and the inner circumferential surface of the second connector 1230 may be partially plated in the shape of a pin, or may respectively be provided with a recess and a protrusion so that the plated portions thereof can be easily coupled to each other.

Although, in this embodiment, the outer garment 1100 and the inner garment 1200 are connected to each other using the connectors, the embodiment may further include a piece of Velcro tape, a snap button or a fastener as an auxiliary means for connecting the outer garment 1100 and the inner garment 1200 to each other.

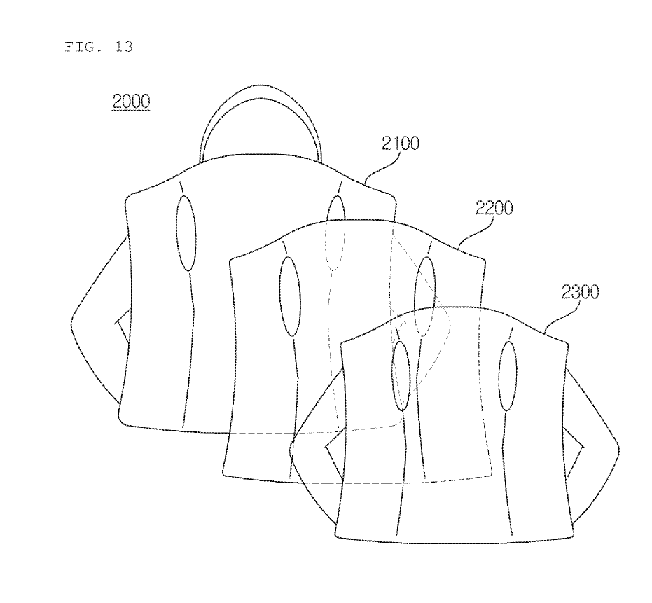

FIG. 12 is a view illustrating light emission from the light-emitting unit in the functional clothing according to the embodiment of the present invention.

The functional clothing according to the present invention includes a gyro sensor for sensing the inclination of the user's body. When the user moves or uses transportation such as a bike in the dark, the gyro sensor may sense the inclination of the user's body and may activate the light-emitting unit such that light is emitted from a portion that corresponds to the side to which the user's body is inclined or a portion opposite thereto. This gives people moving together with the user or people around the user information that enables the people to appropriately cope with the situation. As shown in FIG. 12, when the user changes the direction of travel of the bike and thus the user's body is inclined in one direction, among the light-emitting units attached to the arms of the clothing, the light-emitting unit 1110 that is positioned at a portion corresponding to the direction in which the user's body is inclined emits light, thereby informing other people of the moving direction of the bike.

Meanwhile, the functional clothing according to the present invention may further include a temperature sensor. The temperature sensor may be positioned inside the inner garment in order to sense the user's body temperature. The user's body temperature may rise or drop within a predetermined range due to outdoor activity. The temperature sensor may sense the user's body temperature and may determine whether the user's body temperature is within a normal range. For example, when the user is in distress, the user's body temperature may drop. When the sensed temperature is lower than the predetermined value, the temperature sensor may activate all of the light-emitting units to emit light, thereby indicating the distress situation. In order to more accurately determine a distress situation, setting may be performed to determine that the user is in distress only when a low-temperature state is maintained for a predetermined time. In another embodiment, the user's movement may be sensed by the gyro sensor, and it may be determined that the user is in distress when the user's movement is not sensed for a long time while wearing the clothing. The functional clothing may be provided with a communication module, whereby the functional clothing may transmit information about the position of the user to a pre-registered contact or a nearby police station in addition to emitting light using the light-emitting units.

FIG. 13 is a view illustrating functional clothing according to another embodiment of the present invention.

As shown in FIG. 13, the functional clothing 2000 according to the present invention may include an outer garment 2100, an intermediate garment 2200, and an inner garment 2300. Although, in the previous embodiment, the organic solar cell, the wire and the battery are mounted to the inner garment, this embodiment may be configured such that the organic solar cell, the wire and the battery are mounted to the intermediate garment and such that the outer garment and the inner garment are separated from the intermediate garment for washing. Here, the intermediate garment 2200, to which the organic solar cell, the wire and the battery are mounted, may be formed of a mesh material. In the case in which the intermediate garment 2200 is formed of a mesh material, because it has good air permeability and good moisture permeability, the wearing sensation is improved.

The functional clothing of the present invention is capable of producing electricity by mounting the organic solar cell to outdoor clothing and is also capable of providing various other functions for outdoor clothing. In addition, it is possible to separate the outer garment and the inner garment from each other and to wash the outer garment.

Exemplary embodiments of the present invention disclosed in this specification and drawings are suggested as a specific example to easily describe the present invention and to help understanding thereof and do not limit the scope of the present invention. It will become apparent to a person having ordinary skill in the art that, in addition to exemplary embodiments disclosed herein, various modifications can be made without departing from the scope of the invention.

### DESCRIPTION OF REFERENCE NUMERALS

1000: functional clothing

1100: outer garment

1110: light-emitting unit

1200: inner garment

1210: organic solar cell

1220: wire

1222: electromagnetic-wave-shielding cloth

1130: first connector

1230: second connector

1. An article of functional clothing comprising:
an outer garment provided with a light-emitting unit, the light-emitting unit being detachable from the outer garment; and
an inner garment detachably coupled to the outer garment, the inner garment being provided with an organic solar cell and having a wire formed thereat.

2. The article according to claim 1, wherein the wire is formed of one selected from among silver, copper, nickel, carbon black, graphite, and metal oxide.

3. The article according to claim 1, wherein the wire is embodied as a fabric strap coated with one selected from among silver, copper, nickel, carbon black, graphite, and metal oxide.

4. The article according to claim 1, wherein electromagnetic-wave-shielding cloth is placed over the wire and is sewn.

5. The article according to claim 1, wherein the outer garment and the inner garment are electrically connected to each other by connectors.

6. The article according to claim 1, wherein the inner garment is further provided with a gyro sensor, the gyro sensor sensing inclination of a user's body and activating the light-emitting unit to emit light in accordance with a sensing result.

7. The article according to claim 1, wherein the inner garment is further provided with a temperature sensor, and when a user's body temperature falls below a predetermined value, the temperature sensor activates the light-emitting unit to emit light.

8. An article of functional clothing comprising:
an outer garment provided with a light-emitting unit, the light-emitting unit being detachable from the outer garment;
an intermediate garment detachably coupled to the outer garment, the intermediate garment being provided with an organic solar cell and having a wire formed thereat; and
an inner garment detachably coupled to the intermediate garment.

9. The article according to claim 8, wherein the intermediate garment is formed of a mesh material.

10. The article according to claim 2, wherein electromagnetic-wave-shielding cloth is placed over the wire and is sewn.

11. The article according to claim 2, wherein the outer garment and the inner garment are electrically connected to each other by connectors.

12. The article according to claim 2, wherein the inner garment is further provided with a gyro sensor, the gyro sensor sensing inclination of a user's body and activating the light-emitting unit to emit light in accordance with a sensing result.

13. The article according to claim 2, wherein the inner garment is further provided with a temperature sensor, and when a user's body temperature falls below a predetermined value, the temperature sensor activates the light-emitting unit to emit light.
